(19) United States
(12) Patent Application Publication
(10) Pub. No.: US 2003/0229829 A1
(43) Pub. Date: Dec. 11, 2003

(54) Data transmission apparatus and method

(76) Inventor: Yasuyo Maruwaka, Yokohama-shi (JP)

Correspondence Address: STEVENS, DAVIS, MILLER & MOSHER, L.L.P., Suite 850, 1615 L Street, N.W., Washington, DC, 20036, US

(21) Appl. No.: 10/440,315

(22) Filed: May 19, 2003

(30) Foreign Application Priority Data
May 21, 2002 (JP) 2002-146786

(51) Int. Cl. G06F 12/06; G06F 11/00; G01R 31/28

(52) U.S. Cl. 714/712; 345/571

(57) ABSTRACT

In data on which TrCH 1 and TrCH 2 is multiplexed, data 403 of TrCH 1 is written in from row 0 (401-1) of column 0 (402-1) to row 13 (401-14) of column 4 (402-5) from left to right of data write block 400 for second interleaving. Then, data 404 of TrCH 2 is written from row 13 (401-14) of column 5 (402-6) to row 14 (401-15) of column 29 (402-30) through row 14 (401-15) of column 0 (402-1). The written data is read from data write block 400 in the predetermined order in a direction, upwardly or downwardly, different for each column to map on each slot. It is thereby possible to demodulate the data accurately even when an interference component overlaps a fragment of data of a channel.

### BACKGROUND OF THE INVENTION

1. Field of the Invention

The present invention relates to a data transmission apparatus and method for permuting a data sequence to transmit.

2. Description of the Related Art

In multiplexing data of a plurality of transport channels (hereinafter referred to as “TrCH”) to transmit, combining and transmitting data for each TrCH sometimes results in a case that a receiving side cannot decode the data on a specific TrCH when errors occur successively during communications. As processing to avoid such a situation, there is interleaving in which a transmitting side separates data of TrCH into a plurality of fragments, inserts a separated data fragment of another TrCH between the separated data fragments of the TrCH, and thus rearranges the data. When the data is separated by interleaving and transmitted, since the data of each TrCH is separated, an error occurs on only part of the data of each TrCH even when errors occur successively during communications, and it is possible to avoid the situation that only specific TrCH cannot be decoded. The interleaving includes first interleaving which is performed on a frame basis for each TrCH, and second interleaving which is performed on a per bit basis after multiplexing TrCHs.

FIGS. 1 and 2 illustrate a conventional interleaving method. FIG. 1 shows matrix-shaped data write block 10 for second interleaving with data 13 of TrCH 1 and data 14 of TrCH 2 written therein. In the block 10, with respect to data 13 of TrCH 1 that is written from left as viewed in the figure, 30 bits are written in row 0 (11-1), another 30 bits are written in row 1 (11-2) after row 0 (11-1) is filled, similar processing is repeated subsequently, and when data is written up to row 13 (11-14) of column 5 (12-6), the data write of data 13 of TrCH 1 is finished. Then, data 14 of TrCH 2 is written from row 13 (11-14) of column 6 (12-7) to row 14 (11-15) of column 29 (12-30), and the data write is finished. In other words, all the data is written in data write block 10 in the same direction.

Then, data is read in the order described in the specification, TS25.212Ver.3.5.0 of 3rd Generation Partnership Project (3GPP), and mapped as shown in FIG. 2. In addition, all the data is read from data write block 10 in the same direction. Mapped data composes fifteen slots, data of column 0 (12-1) and data of column 19 (12-20) is mapped on slot 0, data of column 10 (12-11) and data of column 5 (12-6) is mapped onto slot 1, and subsequently, data of two columns is mapped on each slot in the order in which the columns are read. After mapping, data 14 of TrCH 14 is disposed between data 13 of TrCH 1 at periods of half a slot. The data mapped onto each slot is spread with a channelization code, multiplexed on other channels, and transmitted.

However, in the conventional data transmission apparatus, since data of TrCH to be transmitted in the same frame is disposed at periods of half a slot, when an interference component overlaps data with a small number of data items at periods of one slot, half or more of the data of the channel is erroneous, and the data cannot be decoded accurately even after performing error correction.

### SUMMARY OF THE INVENTION

It is an object of the present invention to provide a data transmission apparatus and method enabling data to be decoded accurately even when an interference component overlaps the data with a small data amount at constant periods.

The object is achieved by arbitrarily varying the order of rows in which data is written in writing data in a data write block for data sequence permutation, or arbitrarily varying the direction in which the data is read from the data write block on a column basis, and inserting data of TrCH 2 into data of TrCH 1 on a per bit basis at periods obtained from the number of data items of TrCH 2 in inserting the data of TrCH 2 into the data of TrCH 1 to obtain a single successive data item.

### BRIEF DESCRIPTION OF THE DRAWINGS

The above and other objects and features of the invention will appear more fully hereinafter from a consideration of the following description taken in connection with the accompanying drawings wherein one example is illustrated by way of example, in which:

FIG. 1 is a diagram illustrating a conventional data permutation method;

FIG. 2 is a diagram illustrating a state after conventional mapping:

FIG. 3 is a block diagram illustrating a configuration of a data transmission apparatus according to a first embodiment of the present invention;

FIG. 4 is a block diagram illustrating another configuration of a data transmission apparatus according to the first embodiment of the present invention;

FIG. 5 is a block diagram illustrating a configuration of a data sequence permutation section according to the first embodiment of the present invention;

FIG. 6 is a diagram illustrating a data sequence permutation method according to the first embodiment of the present invention;

FIG. 7 is a diagram illustrating a state after mapping according to the first embodiment of the present invention;

FIG. 8 is a diagram illustrating a data sequence permutation method according to a second embodiment of the present invention;

FIG. 9 is a diagram illustrating a state after mapping according to the second embodiment of the present invention;

FIG. 10 is a block diagram illustrating a configuration of a data transmission apparatus according to a third embodiment of the present invention;

FIG. 11 is a block diagram illustrating another configuration of a data transmission apparatus according to the third embodiment of the present invention;

FIG. 12 is a block diagram illustrating a configuration of a data disposing section according to the third embodiment of the present invention;

FIG. 13 is a flow diagram illustrating the operation of the data disposing section according to the third embodiment of the present invention:

FIG. 14 is a diagram illustrating TrCH according to the third embodiment of the present invention;

FIG. 15 is a diagram illustrating a converted data sequence according to the third embodiment of the present invention; and

FIG. 16 is a diagram illustrating another converted data sequence according to the third embodiment of the present invention.

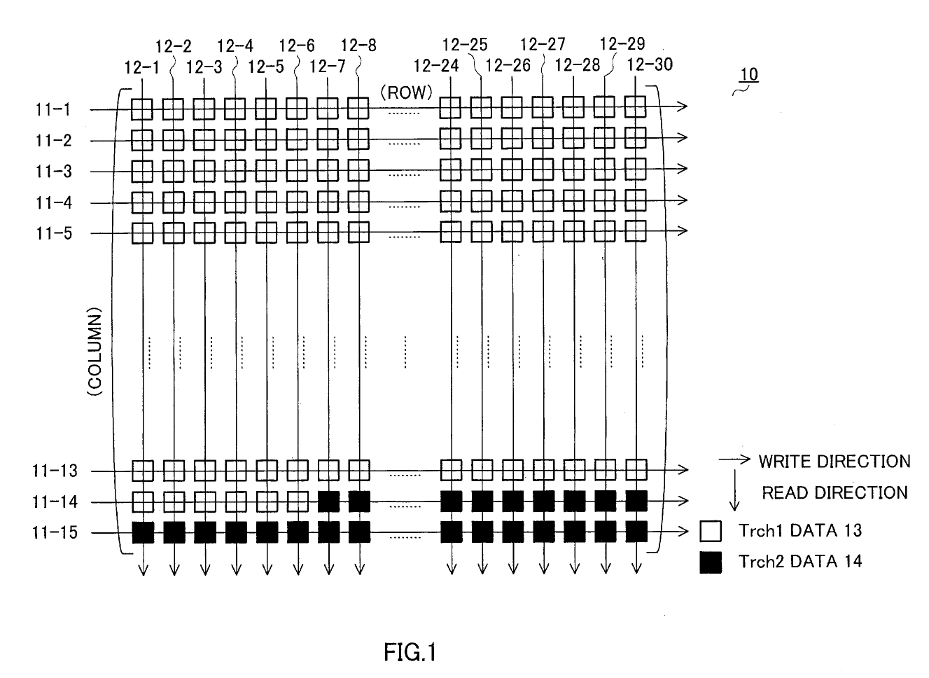

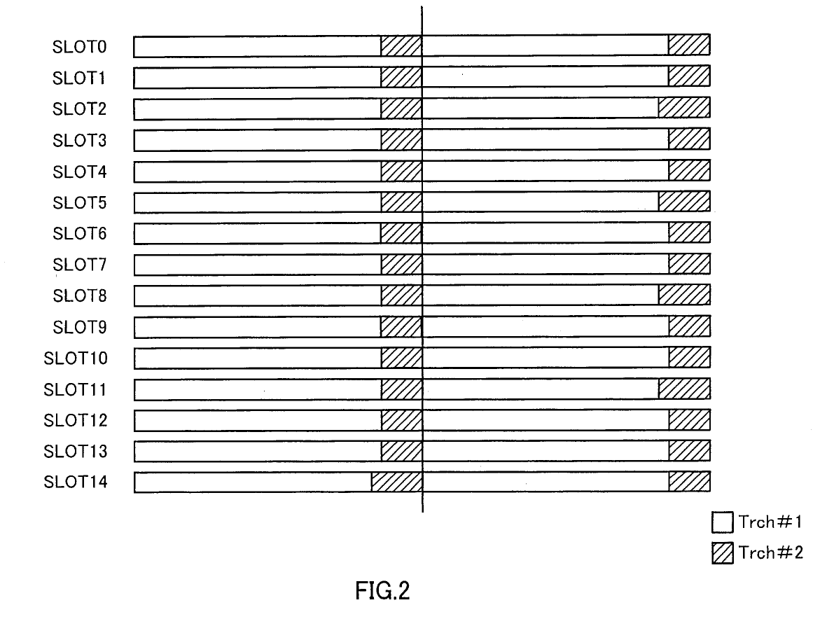

### DETAILED DESCRIPTION OF THE PREFERRED EMBODIMENTS

(First Embodiment)

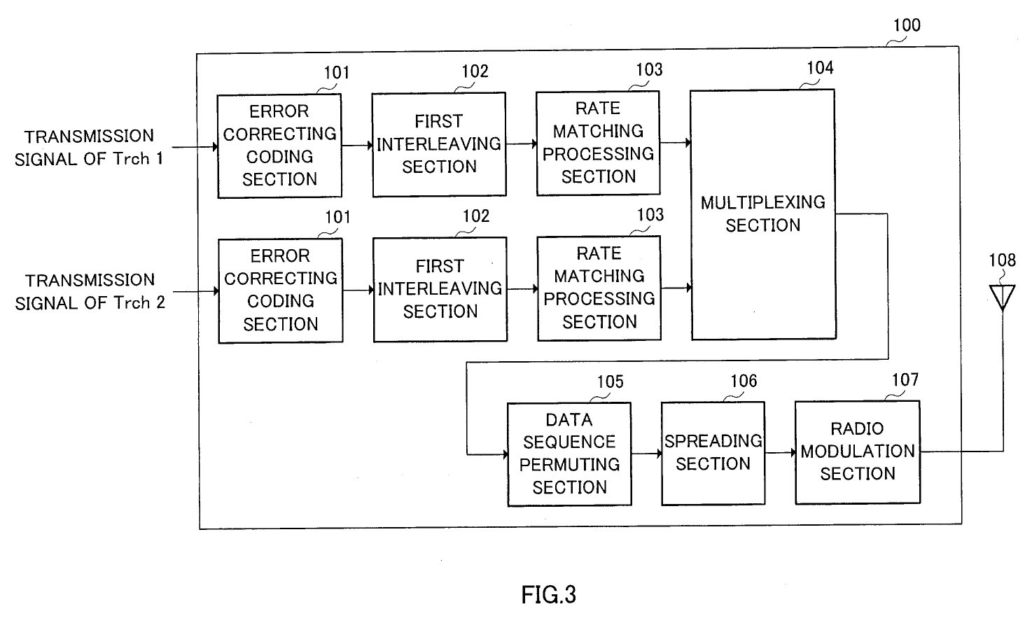

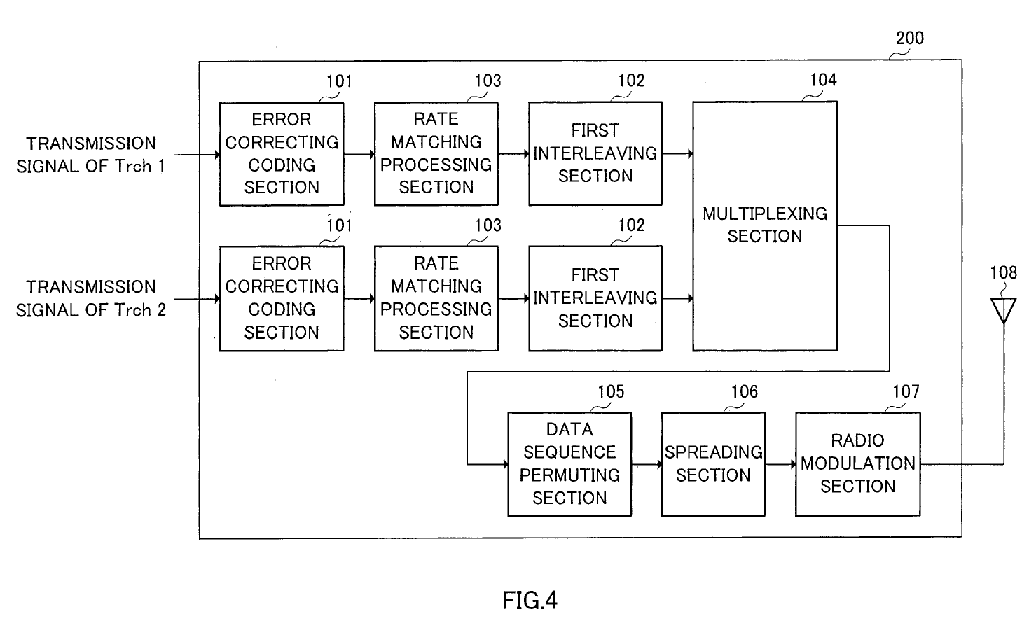

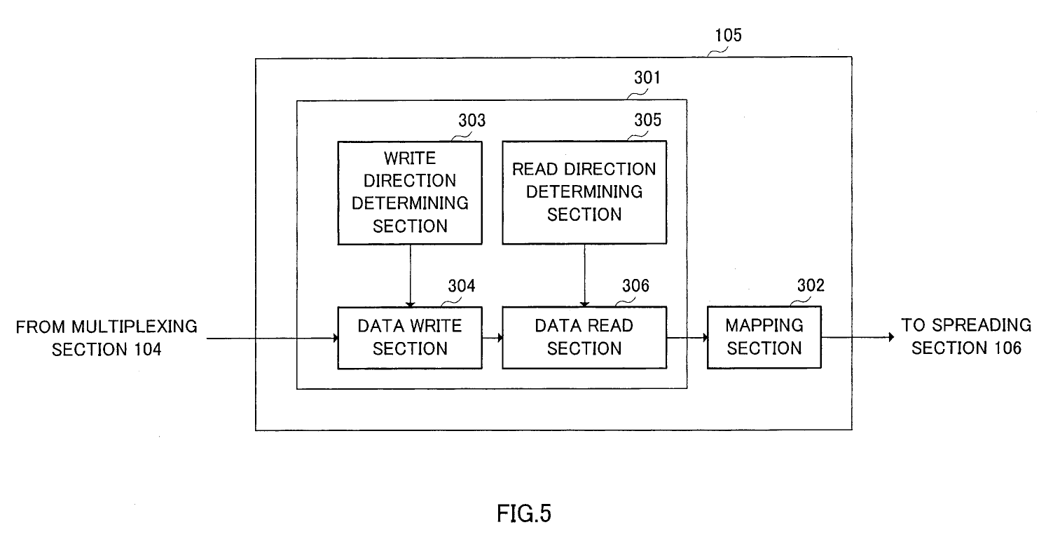

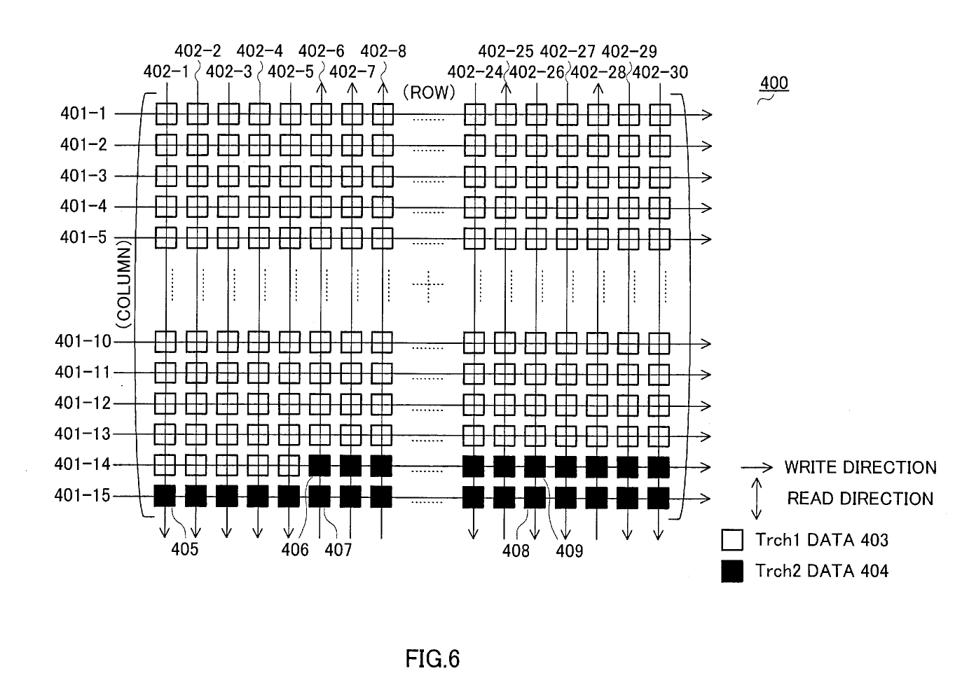

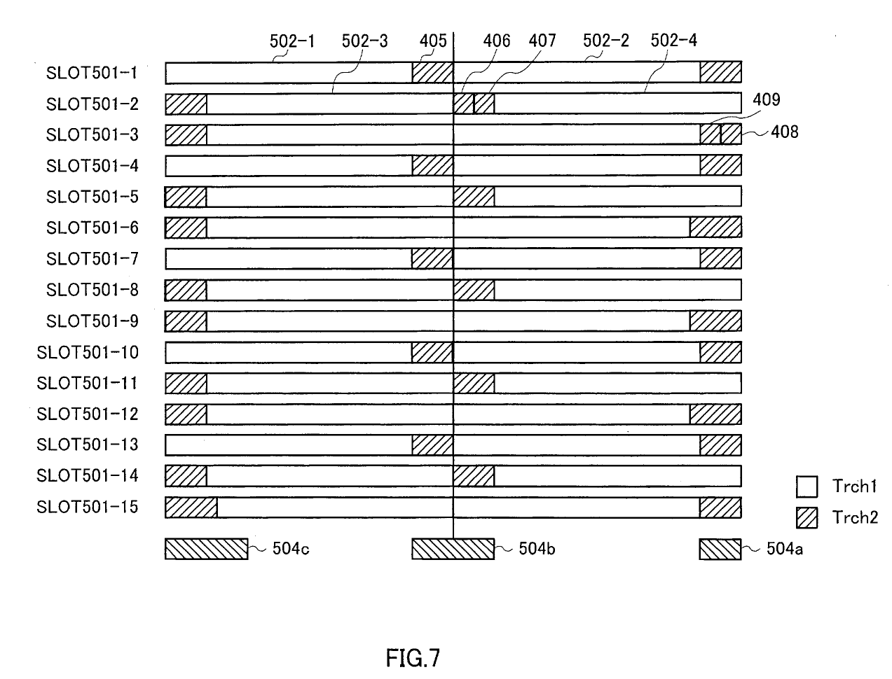

FIG. 3 is a block diagram illustrating a configuration of a data transmission apparatus when the data transmission apparatus according to the first embodiment of the present invention is used in a mobile station apparatus. FIG. 4 is a block diagram illustrating a configuration of a data transmission apparatus when the data transmission apparatus is used in a base station apparatus. FIG. 5 is a block diagram illustrating a configuration of data sequence permuting section 105. FIG. 6 illustrates data arranged in a data write block. FIG. 7 is a diagram illustrating data mapped onto slots after being read from the data write block.

Data transmission apparatus 100 is principally comprised of error correcting coding section 101, first interleaving section 102, rate matching processing section 103, multiplexing section 104, data sequence permuting section 105, spreading section 106, radio modulation section 107 and antenna 108.

Error correcting coding section 101 performs error correcting coding on transmission signals of Transport Channel (hereinafter referred to as “TrCH”) 1 and transmission signals of TrCH 2 to output to first interleaving section 102. First interleaving section 102 changes the order on a frame basis for each TrCH to output to rate matching processing section 103. Using a rate matching parameter, rate matching processing section 103 thins or inserts the data of each TrCH on a per bit basis so that the data of each TrCH is accommodated in a frame on a physical channel after multiplexing, and outputs the resultant to multiplexing section 104. In addition, the subsequent processing is performed on the physical channel. Multiplexing section 104 multiplexes respective data of TrCHs to output to data sequence permuting section 105.

Data sequence permuting section 105 permutes a sequence of data multiplexed in multiplexing section 104 on a per bit basis for each TrCH to output to spreading section 106. In addition, data sequence permuting section 105 will be described specifically later.

Spreading section 106 spreads a transmission signal input from data sequence permuting section 105 with a channelization code to output to radio modulation section 107. Radio modulation section 107 converts the transmission signal into a radio signal, and transmits the radio signal from antenna 108. Data of TrCH 1 and TrCH 2 is different types of data such as speech and image.

Data transmission apparatus 200 is the same as data transmission apparatus 100 as shown in FIG. 4 except that rate matching processing section 103 and first interleaving section 102 are exchanged in the order, and descriptions of the apparatus 200 are omitted.

A configuration of data sequence permuting section 105 will be described below. Data sequence permuting section 105 is principally comprised of second interleaving section 301 and mapping section 302. Second interleaving section 301 is principally comprised of write direction determining section 303, data write section 304, read direction determining section 305 and data read section 306. Write direction determining section 303 determines the order of rows to which data is written in writing the data in data write block 400 described later, and outputs the determined order to data write section 304. Based on the write order input from write direction determining section 303, data write section 304 writes the transmission data input from multiplexing section 104 in data write block 400 to output to data read section 306. Read direction determining section 305 determines for each column the direction in which the data written in data write block 400 is read from the block 400, and outputs the determined read direction to data read section 306. Based on the read direction input from read direction determining section 305, data read section 306 reads out the transmission data input from data write section 304 from data write block 400 to output to mapping section 302. Mapping section 302 that is a disposing section maps for each slot the transmission data input from data read section 306 in the order in which the data is read to output to spreading section 106.

A data write method in data write section 304 in data sequence permuting section 105 will be described below with reference to FIG. 6. Data sequence permuting section 105 permutes the data sequence using data write block 400. Data write block 400 forms a matrix and is composed of 15 rows (from row 0 (401-1) to row 14 (401-15)) and 30 columns (from column 0 (402-1) to column 29 (402-30)) In addition, the numbers of columns and rows in data write block 400 are arbitrary. The order in which data is written is determined in write direction determining section 303, and based on the determination, data is written in data write block 400. Data 403 of TrCH 1 is written in data write block 400 from left to right as viewed in FIG. 6. First starting with row 0 (401-1) of column 0 (402-1), data is written up to row 0 (401-1) of column 29 (402-30), next written in row 1 (401-2) of column 0 (402-1), subsequently written up to row 12 (401-13) of column 29 (402-30) row by row, and written up to row 13 (401-14) of column 4 (402-5). Then, data 404 of TrCH 2 is written in data write block 400.

Starting with row 13 (401-14) of column 5 (402-6) data 404 of TrCH 2 is written up to row 13 (401-14) of column 29 (402-30), next written in row 14 (401-15) of column 0 (402-1), and written up to row 14 (401-15) of column 29 (402-30), and the write ends.

In addition, in FIG. 6, while data of each TrCH of from row 5 (401-6) to row 9 (401-10) is omitted, data 403 of TrCH 1 is written from row 5 (401-6) to row 9 (401-10) all from left to right as viewed in FIG. 6. Further, while data of each TrCH of from column 8 (402-9) to column 22 (402-23) is omitted, data 403 of TrCH 1 is written in from row 0 (401-1) to row 12 (401-13) of column 8 (402-9) to column 22 (402-23), and data 404 of TrCH 2 is written in from row 13 (401-14) to row 14 (401-15) of column 8 (402-9) to column 22 (402-23).

A data read method in data read section 305 in data sequence permuting section 105 will be described below with reference to FIG. 6. Read direction determining section 305 determines to read data in the order of columns as described in 3rd Generation Partnership Project (3GPP) Technical Specification, TS25.212 Ver3.5.0. The order of columns from which data is read out is column 0, column 20, column 10, column 5, column 15, column 25, column 3, column 13, column 23, column 8, column 18, column 28, column 1, column 11, column 21, column 6, column 16, column 26, column 4, column 14, column 24, column 19, column 9, column 29, column 12, column 2, column 7, column 22, column 27 and column 17. Read direction determining section 305 further determines the direction in which data is read out for each column, and based on the determined read direction, reads out the data.

Data is read from bottom in FIG. 6 in columns 0 (402-1) to 4 (402-5), columns 11 (402-12) to 14 (402-15), column 17 (402-18), column 20 (402-21), column 25 (402-26), column 26 (402-27), column 28 (402-29) and column 29 (402-30), while being read from top in FIG. 6 in columns 5 (402-6) to 10 (402-11), column 15 (402-16), column 16 (402-17), column 18 (402-19), column 19 (402-20), columns 21 (402-22) to 24 (402-25), and column 27 (402-28). Thus, the data is read out in two directions, upward direction and downward direction, which are perpendicular to the data write direction and are parallel to each other. In addition, upward and downward directions in which data is read out for each column are not limited to the case of this embodiment, and are arbitrary.

A state where the data read from matrix 400 is mapped will be described with reference to FIG. 7. The data read in data read section 306 is read out in the column read order as described above, and mapping section 302 disposes data of two columns on each of slots 501-1 to 501-15. The number of all the slots is 15. In FIG. 7, with respect to data disposed on right side of each slot, the first bit data in the read direction is disposed in rightmost of each slot, and subsequent bit data in the read direction is disposed from right to left in each slot. Further, with respect to data disposed on left side of each slot, the first bit data in the read direction is disposed at the center of each slot, and subsequent bit data is disposed from right to left.

In this way, data of column 0 (402-1) is disposed in left half 502-1 of slot 501-1, data of column 20 (402-19) is disposed in right half 502-2 of slot 501-1, data of column 10 (402-11) is disposed in left half 502-3 of slot 501-2, data of column 5 (402-6) is disposed in right half 502-4 of slot 501-2, and similarly, each slot is assigned data of two columns in the read column order as described above. In other words, data 405 of TrCH 2 of column 0 (402-1) is disposed at the center of slot 501-1, data 406 and 407 of TrCH 2 of column 5 (402-6) is disposed at the center of slot 501-2, data 408 and 409 of TrCH 2 of column 25 (402-26) is disposed at the right end of slot 501-3, and subsequent data is similarly disposed.

As a result of such an arrangement, as shown in FIG. 7, with respect to data 404 of TrCH 2 in all the slots, the number of data items at the left end, the number of data items at the center, and the number of data items at the right ends are all 10, and thus data 404 of TrCH 2 is disposed while being equally dispersed. FIG. 7 shows slots 501-1 to 501-15 divided vertically, but actually slots 501-1 to 501-15 are coupled in this order to be a single item of continuous data. Accordingly, by arranging as shown in FIG. 7, data of TrCH 2 is disposed at periods of half a slot, while being dispersed at positions before or after half the slot. When the difference is 0 between the number of columns read upwardly and the number of columns read downwardly, data 404 of TrCH 2 is dispersed the most equally, and as the difference is increased between the number of columns read upwardly and the number of columns read downwardly, data 404 of TrCH 2 is more collected at the left end, at the center or at the right end. Accordingly, reading out columns upwardly and downwardly the same number of times causes least effects due to interference component to be imposed.

A case that an interference component is present on thus arranged data will be described below with reference to FIG. 7. An example of the interference component is data of a channel that is not orthogonal to the channelization code multiplied on the physical channel. When data is multiplexed on such channel data to be transmitted, the channel data interferes with the data, and at a part multiplexed on the channel data, data is not obtained accurately after being despread.

A case will be described first where interference component 504a is present at the right end of each slot. In this case, interference component 504a overlaps data 404 of TrCH 2 at periods of one slot, and ten items of data 404 of TrCH 2 at the right end all contain errors. However, since it is possible to accurately demodulate ten items of data 404 of TrCH 2 at the left end and ten items of data 404 of TrCH 2 at the center i.e. total twenty items of data 404 of TrCH 2, the errors of data 404 of TrCH 2 containing the errors at the right end can be corrected by error correction. Accordingly, it is possible to prevent occurrences of a state where data 404 of TrCH 2 cannot be decoded accurately due to the interference caused by the data of a channel that is not orthogonal to the channelization code multiplied on the physical channel. Further, also in the case where an interference component is present other than the data of a channel that is not orthogonal to the channelization code multiplied on the physical channel, since data 404 of TrCH 2 is discrete as compared to the conventional case, it is possible to decrease the error rate of the data subjected to error correction.

A case will be described below where interference component 504b is present at the center of each slot. In this case, interference component 504b overlaps data 404 of TrCH 2 at periods of one slot, and ten items of data 404 of TrCH 2 at the center all contain errors. However, since it is possible to accurately demodulate ten items of data 404 of TrCH 2 at the left end and ten items of data 404 of TrCH 2 at right end i.e. total twenty items of data 404 of TrCH 2, the errors of data 404 of TrCH 2 containing the errors at the center can be corrected by error correction. Accordingly, it is possible to prevent occurrences of a state where data 404 of TrCH 2 cannot be decoded accurately due to the interference caused by the data of a channel that is not orthogonal to the channelization code multiplied on the physical channel. Further, also in the case where an interference component is present other than the data of a channel that is not orthogonal to the channelization code multiplied on the physical channel, since data 404 of TrCH 2 is discrete as compared to the conventional case, it is possible to decrease the error rate of the data subjected to error correction.

A case will be described below where interference component 504c is present at the left end of each slot. In this case, interference component 504c overlaps data 404 of TrCH 2 at periods of one slot, and ten items of data 404 of TrCH 2 at the left end all contain errors. However, since it is possible to accurately demodulate ten items of data 404 of TrCH 2 at the right end and ten items of data 404 of TrCH 2 at the center i.e. total twenty items of data 404 of TrCH 2, the errors of data 404 of TrCH 2 containing the errors at the center can be corrected by error correction. Accordingly, it is possible to prevent occurrences of a state where data 404 of TrCH 2 cannot be demodulated accurately due to the interference caused by the data of a channel that is not orthogonal to the channelization code multiplied on the physical channel. Further, also in the case where an interference component is present other than the data of a channel that is not orthogonal to the channelization code multiplied on the physical channel, since data 404 of TrCH 2 is discrete as compared to the conventional case, it is possible to decrease the error rate of the data subjected to error correction.

Thus, according to the data transmission apparatus of this embodiment, data 404 of TrCH 2 subjected to mapping is dispersed equally at the right end, center and left end, and since data 404 of TrCH 2 is small in number which overlaps a channel that is not orthogonal to the channelization code multiplied on the physical channel when being multiplexed on the channel that is not orthogonal, it is possible to prevent occurrences of a state where data 404 of TrCH 2 cannot be decoded accurately due to the interference caused by the data of the channel that is not orthogonal. Further, also in the case where an interference component is present other than the data of a channel that is not orthogonal to the channelization code multiplied on the physical channel, since data 404 of TrCH 2 is discrete as compared to the conventional case, it is possible to decrease the error rate of the data subjected to error correction, and to prevent occurrences of a state where the data cannot be decoded accurately due to the interference component occurring during communications.

In addition, while in this embodiment the write direction and read direction are perpendicular to each other, the read direction may be two different directions parallel to the write direction.

(Second Embodiment)

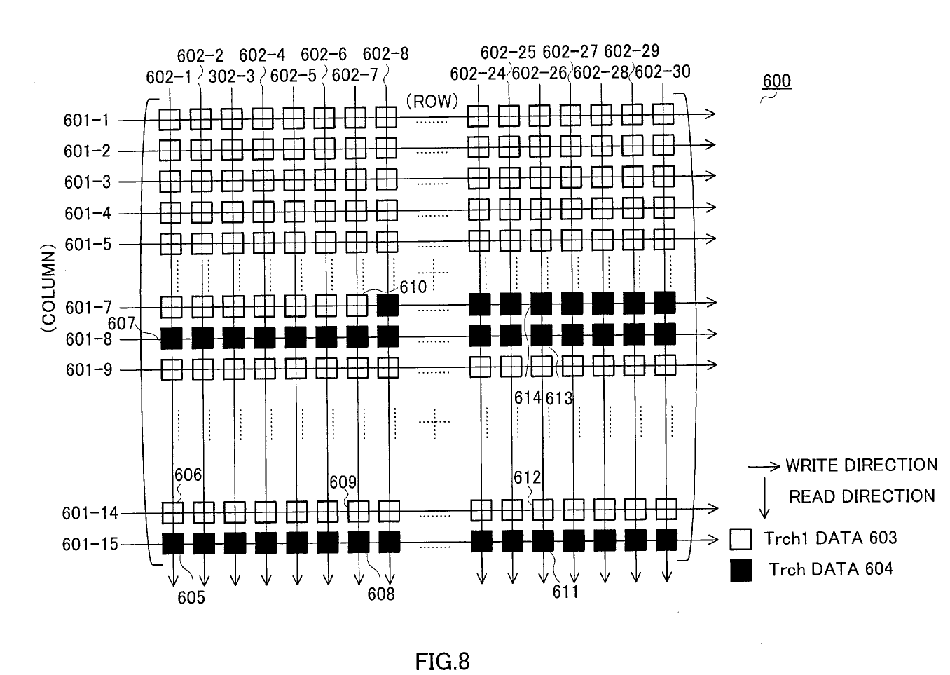

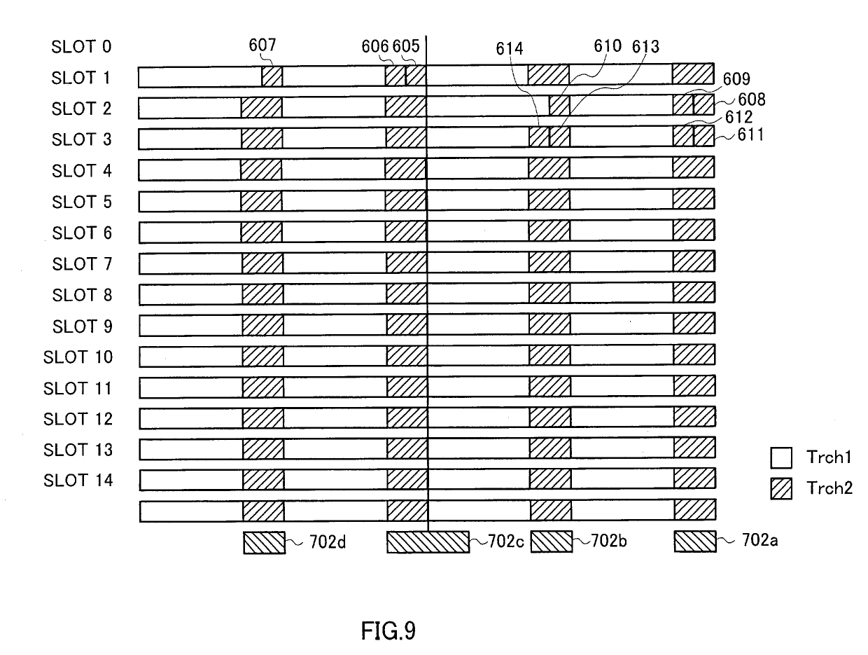

FIG. 8 is a diagram illustrating the data write in data write block 600 and data read from data write block 600 in data sequence permuting section 105 according to the second embodiment of the present invention, and FIG. 9 is a diagram illustrating data after mapping. In this embodiment, a configuration of the data transmission apparatus used in a mobile station apparatus is the same as that in FIG. 3, a configuration of the data transmission apparatus used in a base station apparatus is the same as that in FIG. 4, a configuration of data sequence permuting section 105 is the same as that in FIG. 5, and therefore, descriptions thereof are omitted.

A method is first explained of writing data in data write block 600 in data write section 304 in data sequence permuting section 105. Data write block 600 is comprised of 15 rows, from row 0 (601-1) to row 14 (601-15) and 30 columns, from column 0 (602-1) to column 29 (602-30). Assuming that the total number of rows is n, write direction determining section 303 disposes data in row m and row (((n+1)/2)+m), and thus the data is written in two rows obtained for each value of m while increasing m by 1 starting with 0. In addition, m is an integer of 0 or more and varied in a range of (((n+1)/2)+m) to n [(((n+1)/2)+m)≦n]. In this embodiment, since the value of n is 15, write direction determining section 303 determines the order of rows to which data is inserted as row 0, row 8, row 1, row 9, row 2, row 10, row 3, row 11, row 4, row 12, row 5, row 13, row 6, row 14 and row 7. In addition, when n+1 is not divisible by 2, the quotient is rounded down to the whole number.

When data is written in the above-mentioned order, as shown in FIG. 8, data 604 of TrCH 2 is disposed in columns 7 (602-8) to 29 (602-30) of row 6 (601-7), columns 0 (602-1) to 29 (602-30) of row 7 (601-8), and columns 0 (602-1) to 29 (602-30) of row 14 (601-15). In addition, in FIG. 8, since descriptions on the data of each TrCH in from row 4 (601-5) to row 5 (601-6) and from row 9 (601-10) to row 12 (601-13) are omitted, data 603 of TrCH 1 is written all in from row 4 (601-5) to row 5 (601-6) and from row 9 (601-10) to row 12 (601-13).

A data read method in data read section 306 in data sequence permuting section 105 will be described below with reference to FIG. 8. The data is read based on the read direction determined in read direction determining section 305, and read downwardly in all the columns. Read direction determining section 305 determines to read data in the order of columns as described in 3rd Generation Partnership Project (3GPP), Technical Specification, TS25.212 Ver3.5.0. The order of columns from which data is read out is column 0, column 20, column 10, column 5, column 15, column 25, column 3, column 13, column 23, column 8, column 18, column 28, column 1, column 11, column 21, column 6, column 16, column 26, column 4, column 14, column 24, column 19, column 9, column 29, column 12, column 2, column 7, column 22, column 27 and column 17.

A state where the data read from matrix 600 is mapped will be described with reference to FIG. 9. In addition, the method of mapping data from data write block 600 on each slot is the same as that in the first embodiment, and descriptions thereof are omitted. By the mapping, data 605, 606 and 607 of TrCH 2 of column 0 (602-1) is disposed at the center and at the center in the left half of slot 701-1, data 608, 609 and 610 of TrCH 2 of column 5 (602-6) is disposed at the right end and at the center in the right half of slot 701-2, data 611, 612, 613 and 614 of TrCH 2 of column 25 (602-26) is disposed at the right end and at the center in the right half of slot 701-3, and subsequent data is similarly disposed. In this way, in FIG. 9, data 604 of TrCH 2 is disposed at the center, right end, center in the right half and center in the left half, and thus is disposed on each slot as four fragments.

FIG. 9 shows slots 701-1 to 701-15 divided vertically, but actually slots 701-1 to 701-15 are coupled in this order to be a single item of continuous data. Accordingly, by arranging as shown in FIG. 9, data of TrCH 2 is disposed at periods of one-fourth a slot.

A case that an interference component is present on thus arranged data will be described below with reference to FIG. 9. A case will be described first where interference component 702a is present at the right end of each slot. In this case, interference component 702a overlaps data 604 of TrCH 2 at periods of one slot, and fifteen items of data 604 of TrCH 2 at the right end all contain errors. However, since it is possible to accurately demodulate fifteen items of data 604 of TrCH 2 at the center in the right half, fifteen items of data 604 of TrCH 2 at the center, and fifteen items of data 604 of TrCH 2 at the center in the left half i.e. total forty-five items of data 604 of TrCH 2, the errors of data 604 of TrCH 2 containing errors at the right end can be corrected by error correction. Accordingly, it is possible to prevent occurrences of a state where data 604 of TrCH 2 cannot be decoded accurately due to the interference caused by the data of a channel that is not orthogonal to the channelization code multiplied on the physical channel. Further, also in the case where an interference component is present other than the data of a channel that is not orthogonal to the channelization code multiplied on the physical channel, since data 604 of TrCH 2 is discrete as compared to the conventional case, it is possible to decrease the error rate of the data subjected to error correction.

A case will be described below where interference component 702b is present at the center in the right half of each slot. In this case, interference component 702b overlaps data 604 of TrCH 2 at periods of one slot, and fifteen items of data 604 of TrCH 2 at the center in the right half all contain errors. However, since it is possible to accurately demodulate fifteen items of data 604 of TrCH 2 at the right end, fifteen items of data 604 of TrCH 2 at the center, and fifteen items of data 604 of TrCH 2 at the center in the left half i.e. total forty-five items of data 604 of TrCH 2, the errors of data 604 of TrCH 2 containing the errors at the center in the right half can be corrected by error correction. Accordingly, it is possible to prevent occurrences of a state where data 604 of TrCH 2 cannot be decoded accurately due to the interference caused by the data of a channel that is not orthogonal to the channelization code multiplied on the physical channel. Further, also in the case where an interference component is present other than the data of a channel that is not orthogonal to the channelization code multiplied on the physical channel, since data 604 of TrCH 2 is discrete as compared to the conventional case, it is possible to decrease the error rate of the data subjected to error correction, and to decode the entire data 604 of TrCH 2 accurately.

A case will be described below where interference component 702c is present at the center of each slot. In this case, interference component 702c overlaps data 604 of TrCH 2 at periods of one slot, and fifteen items of data 604 of TrCH 2 at the center all contain errors. However, since it is possible to accurately demodulate fifteen items of data 604 of TrCH 2 at the right end, fifteen items of data 604 of TrCH 2 at the center in the right half, and fifteen items of data 604 of TrCH 2 at the center in the left half i.e. total forty-five items of data 604 of TrCH 2, the errors of data 604 of TrCH 2 containing the errors at the center can be corrected by error correction. Accordingly, it is possible to prevent occurrences of a state where data 604 of TrCH 2 cannot be decoded accurately due to the interference caused by the data of a channel that is not orthogonal to the channelization code multiplied on the physical channel. Further, also in the case where an interference component is present other than the data of a channel that is not orthogonal to the channelization code multiplied on the physical channel, since data 604 of TrCH 2 is discrete as compared to the conventional case, it is possible to decrease the error rate of the data subjected to error correction.

A case will be described below where interference component 702d is present at the center in the left half of each slot. In this case, interference component 702d overlaps data 604 of TrCH 2 at periods of one slot, and fifteen items of data 604 of TrCH 2 at the center in the left half all contain errors. However, since it is possible to accurately demodulate fifteen items of data 604 of TrCH 2 at the right end, fifteen items of data 604 of TrCH 2 at the center in the right half, and fifteen items of data 604 of TrCH 2 at the center i.e. total forty-five items of data 604 of TrCH 2, the errors of data 604 of TrCH 2 containing the errors at the center in the left half can be corrected by error correction. Accordingly, it is possible to prevent occurrences of a state where data 604 of TrCH 2 cannot be decoded accurately due to the interference caused by the data of a channel that is not orthogonal to the channelization code multiplied on the physical channel. Further, also in the case where an interference component is present other than the data of a channel that is not orthogonal to the channelization code multiplied on the physical channel, since data 604 of TrCH 2 is discrete as compared to the conventional case, it is possible to decrease the error rate of the data subjected to error correction.

Thus, according to the data transmission apparatus of this embodiment, since data 604 of TrCH 2 is dispersed at four portions on each slot, it is possible to prevent occurrences of a state where data 604 of TrCH 2 cannot be decoded accurately due to the interference caused by the data of a channel that is not orthogonal to the channelization code multiplied on the physical channel. Further, in the case where an interference component is present other than the data of a channel that is not orthogonal to the channelization code multiplied on the physical channel, since data 604 of TrCH 2 is discrete as compared to the conventional case, it is possible to decrease the error rate of the data subjected to error correction, and to prevent occurrences of a state where data cannot be decoded accurately due to an interference component occurring during communications.

In addition, while in this embodiment the write direction and read direction are perpendicular to each other, data may be read out in two different directions parallel to the write direction.

(Third Embodiment)

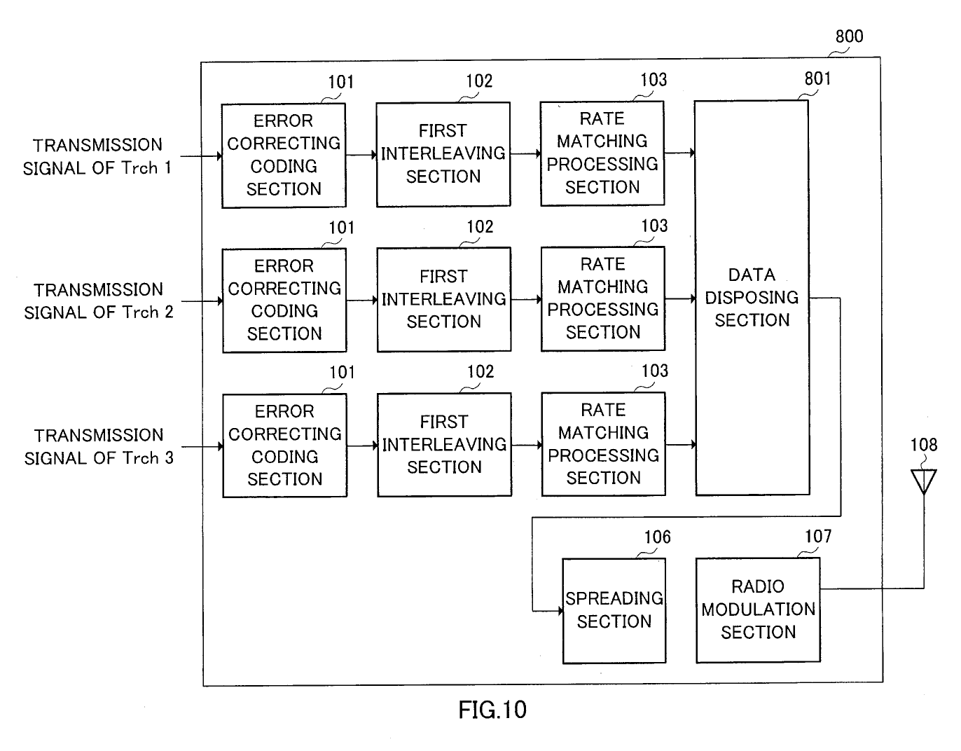

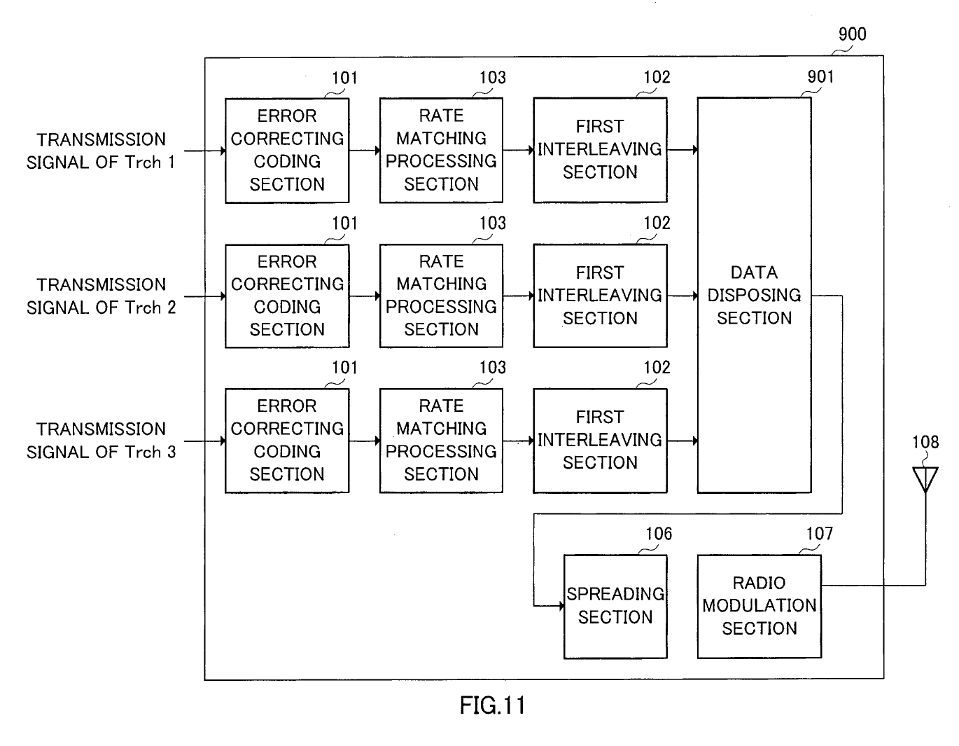

FIG. 10 is a diagram illustrating a configuration of data transmission apparatus 800 which is used in a mobile station apparatus according to the third embodiment of the present invention. FIG. 11 is a diagram illustrating a configuration of data transmission apparatus which is used in a base station apparatus.

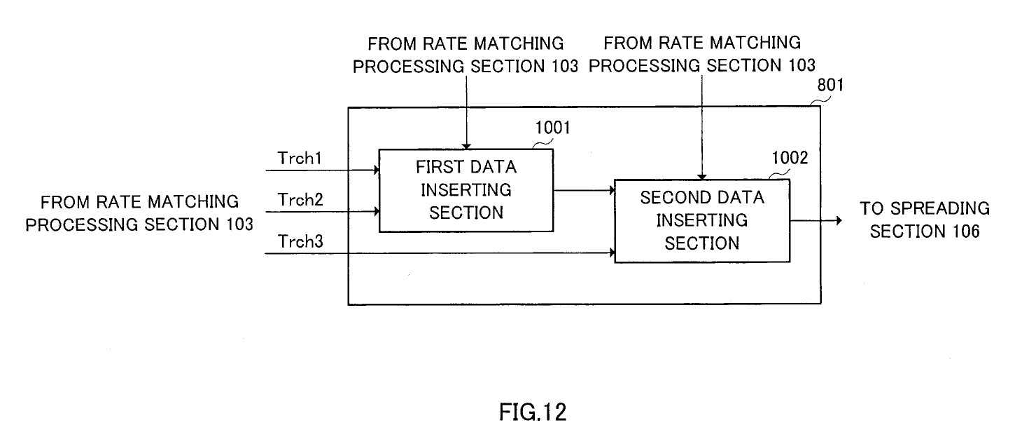

FIG. 12 is a diagram illustrating a configuration of data disposing section 801. In this embodiment, FIG. 10 and FIG. 11 are the same as FIG. 3 and FIG. 4 respectively except that a data disposing section is provided instead of the multiplexing section and the data sequence permutation section and one more error correction coding section, first interleaving section and rate matching processing section are provided corresponding to one more TrCH, and the same sections are assigned the same reference numerals as in FIGS. 3 and 4 to omit descriptions thereof.

Data disposing section 801 in data transmission apparatus 800 inserts data of TrCH 2 input from rate matching processing section 103 into data of TrCH 1 at predetermined periods to multiplex. The section 801 inserts data of TrCH 3 input from rate matching processing section 103 to the data on which the data of TrCH 1 and TrCH 2 is multiplexed to further multiplex. The data multiplexed in data disposing section 801 is output to spreading section 106.

Data disposing section 901 in data transmission apparatus 900 inserts data of TrCH 2 input from first interleaving section 102 into data of TrCH 1 at predetermined periods to multiplex. The section 901 inserts data of TrCH 3 input from first interleaving section 102 into the data on which the data of TrCH 1 and TrCH 2 is multiplexed to further multiplex. The data multiplexed on data disposing section 901 is output to spreading section 106.

The configuration of data disposing section 801 will be described below. Data disposing section 801 is principally comprised of first data inserting section 1001 and second data inserting section 1002. First data inserting section 1001 calculates a period at which the data of TrCH 2 is inserted into the data of TrCH 1 from the number of bits of the data of TrCH 2 input from rate matching processing section 103, inserts the data of TrCH 2 into the data of TrCH 1 at the obtained period to multiplex, and outputs the multiplexed data to second data inserting section 1002. Second data inserting section 1002 calculates a period at which the data of TrCH 3 is inserted into the data on which the data of TrCH 1 and TrCH 2 is multiplexed input from first data inserting section 1001 from the number of bits of the data of TrCH 3 input from rate matching processing section 103, inserts the data of TrCH 3 into the data of on which the data of TrCH 1 and TrCH 2 is multiplexed at the obtained period to further multiplex, and outputs the multiplexed data to spreading section 106. Data disposing section 901 has the same configuration as that in FIG. 12 except that first interleaving section 102 inputs data 403 of TrCH 1 and data 404 of TrCH 2 to first data inserting section 1001 and further inputs data of TrCH 3 to second data inserting section 1102, and descriptions thereof are omitted.

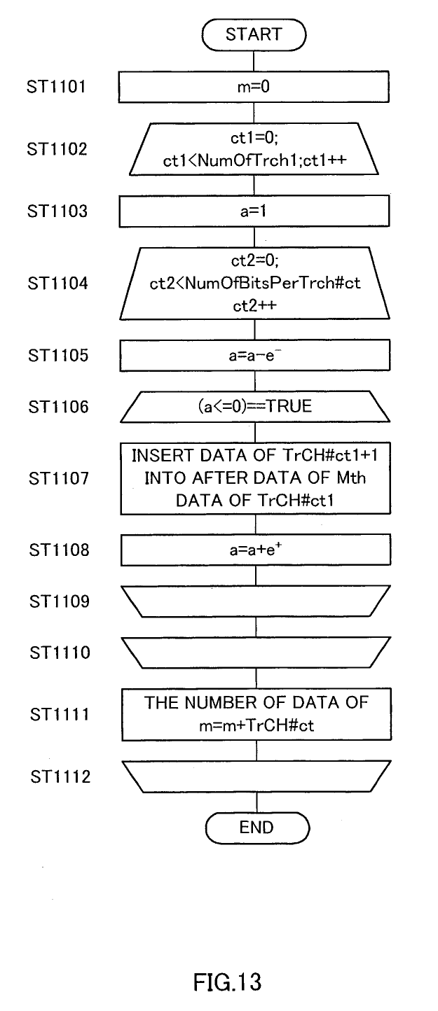

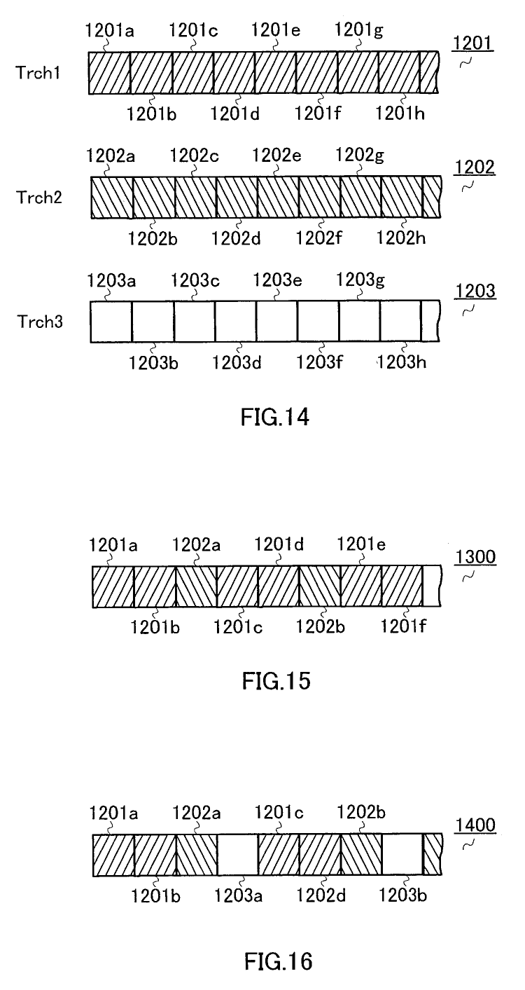

A method of inserting data in data disposing section 801 will be described with reference to FIGS. 13 and 14. In FIG. 13, m is set at 0 (step (hereinafter referred to as “ST”) 1101). Counter 1 is set for 0 only in the first time, and is incremented by 1 except the first time whenever a result of the TrCH number minus 1 is larger than the counter number of counter 1 (ST1102) The processing of ST1102 to ST1112 is repeated until the result of the TrCH number minus 1 decreases below the counter number. First data inserting section 1001 performs the processing of ST1102 to ST1112 of the first time, and second data inserting section 1002 performs the processing of ST1102 to ST1112 of the second time. In addition, the number of times the processing of ST1102 to ST1112 is repeated is a number obtained by subtracting 1 from the TrCH number, and the number of repeating times and the TrCH number are arbitrary.

a is set at 1 (ST1103). Counter 2 is set for 0 only in the first time, and is increased by 1 except the first time whenever the TrCH number 1 is larger than the counter number (ST1104). The processing of ST1104 to ST1110 is repeated until the number of bits of TrCH decreases below the counter number. Next, a is set at a result of a minus e− (ST1105). e− is the number of bits of TrCH#1 (ctl+1) i.e. the number of bits of TrCH to be inserted. It is determined whether the value of a is not more than 0 (ST1106). The processing of ST1106 to ST1109 is repeated until the value of a exceeds 0. When the value of a is 0 or less, data corresponding to one bit of TrCH to be inserted is inserted, while being not inserted when the value of a is more than 0 (ST1107). Next, a is set at a value of a plus e+ (ST1108). e+ is the total number of bits of TrCH #0 to TrCH #ctl i.e. the number of bits of TrCH to which data is inserted. m is set at a value of m plus the number of data items of TrCH (ST1111).

Referring to FIGS. 14 to 16, a method will be described of permuting the data sequence of TrCH 1, TrCH 2 and TrCH 3 on a per bit basis to be continuous data. First data inserting section 1101 inserts the data of TrCH 2 into the data of TrCH 1. The inserting period is obtained using e+ that is the number of bits of TrCH 1 and e− that is the number of bits of TrCH 2. As shown in FIG. 15, one bit, 1202a, of the data of TrCH 2 is inserted into after successive two bits, 1201a and 1201b, of the data of TrCH 1, and at this period, the data of TrCH 2 is inserted up to the final bit of the data of TrCH 1. Then, second data inserting section 1002 inserts the data of TrCH 3 into combined data 1300 in which the data of TrCH 2 is inserted into the data of TrCH 1 as shown in FIG. 15. The inserting period is obtained using e+ that is the number of bits of data on which the data of TrCH 1 and the data of TrCH 2 is multiplexed and e− that is the number of bits of TrCH 3. As shown in FIG. 16, data 1203a of TrCH 3 corresponding to one bit is inserted into after data 1202a to 1202h each of one bit of TrCH 2, and at this period, the data of TrCH 3 is inserted up to the final bit of combined data 1300. The data corresponding to fifteen slots are assigned in the data arrangement as shown in FIG. 16, whereby data 1201 of TrCH 1, data 1202 of TrCH 2 and data 1203 of TrCH 3 becomes a single item of continuous data equal to the multiplexed data.

Thus, according to the data transmission apparatus of this embodiment, since data 1202 of TrCH 2 is inserted into data 1201 of TrCH 1 at predetermined periods to be a single item of continuous data, it is possible to prevent occurrences of a state where data 1202 of TrCH 2 and data 1203 of TrCH 3 cannot be decoded accurately due to the interference caused by the data of a channel that is not orthogonal. Further, also in the case where an interference component is present other than the data of a channel that is not orthogonal to the channelization code multiplied on the physical channel, since data 1202 of TrCH 2 and data 1203 of TrCH 3 is discrete as compared to the conventional case, it is possible to decrease the error rate of the data subjected to error correction, and to prevent occurrences of a state where the data cannot be decoded accurately due to the interference component occurring during communications. Furthermore, since data of each TrCH is rearranged using the rate matching parameter used in rate matching processing in rate matching processing section 103, it is not necessary to set a new criterion for rearranging data of each TrCH, and data sequence permutation processing is simplified, enabling fast processing speed. Moreover, since data permutation by inserting data between TrCHs and multiplexing processing is concurrently performed in the same processing, the processing is simplified and data processing speed is increased.

In addition, in this embodiment, the number of TrCHs is two or three, but may be arbitrary. The period of data disposal of each TrCH may be set arbitrary corresponding to the number of bits of data of each TrCH. Further, in the rate matching processing, when data of TrCH is increased, the period of inserting data is calculated using the rate matching parameter. Applying such an idea, in this embodiment it may be possible to obtain the period of inserting data of TrCH using the rate matching parameter. In order to disperse the data equally, it is preferable that the rate matching parameter used in inserting the data differs from the rate matching parameter used in the rate matching processing.

(Other Embodiments)

While the first to third embodiments describe the case where the data sequence is permuted in data sequence permuting section 105 and others, the present invention is applicable to a case where first interleaving section 102 permuted the data sequence. Further, while the first to third embodiments describe the case where data is transmitted in wireless communications, for example, from a mobile station apparatus to a base station apparatus or from a base station apparatus to a mobile station apparatus, the present invention is applicable to the case where data is transmitted in wired communications.

As described above, according to the present invention, even when an interference component overlaps data with a small data amount at constant periods, it is possible to decode the data accurately.

The present invention is not limited to the above described embodiments, and various variations and modifications may be possible without departing from the scope of the present invention.

This application is based on the Japanese Patent Application No.2002-146786 filed on May 21, 2002, entire content of which is expressly incorporated by reference herein.

What is claimed is:

1. A data transmission apparatus comprising:
a data write section that writes a plurality of kinds of data in a matrix-shaped data write block with a plurality of rows and a plurality of columns;
a data read section that reads out the data in two directions that are different from a direction in which the data is written and are parallel to each other;
a disposing section that disposes the data read out in the data read section in the order in which the data is read out; and
a transmitting section that transmits the data disposed in the disposing section.

2. The data transmission apparatus according to claim 1, wherein the data read section reads out the data in one direction and in the other direction the same number of times.

3. A data transmission apparatus comprising:
a data write section that writes a plurality of data alternately on row m and row (((n+1)/2)+m) (m is an integer of 0 or more and (((n+1)/2)+m)≦n) in a matrix-shaped data write block with n rows and a plurality of columns;
a data read section that reads out the data from the data write block in a direction different from a direction in which the data is written;
a disposing section that disposes the data read out in the data read section in the order in which the data is read out; and
a transmitting section that transmits the data disposed in the disposing section.

4. A data transmission apparatus comprising:
a period calculating section that calculates a period at which second data that is different in kind from first data is inserted into the first data on a per bit basis, from the number of items of data of the second data;
a disposing section that inserts the second data into the first data on a per bit basis at the period obtained in the period calculating section to obtain a single item of continuous data; and
a transmitting section that transmits the data disposed in the disposing section.

5. A base station apparatus provided with a data transmission apparatus, the data transmission apparatus comprising:
a data write section that writes a plurality of kinds of data in a matrix-shaped data write block with a plurality of rows and a plurality of columns;
a data read section that reads out the data in two directions that are different from a direction in which the data is written and are parallel to each other;
a disposing section that disposes the data read out in the data read section in the order in which the data is read out; and
a transmitting section that transmits the data disposed in the disposing section.

6. A mobile station apparatus provided with a data transmission apparatus, the data transmission apparatus comprising:
a data write section that writes a plurality of kinds of data in a matrix-shaped data write block with a plurality of rows and a plurality of columns;
a data read section that reads out the data in two directions that are different from a direction in which the data is written and are parallel to each other;
a disposing section that disposes the data read out in the data read section in the order in which the data is read out; and
a transmitting section that transmits the data disposed in the disposing section.

7. A data transmission method comprising:
a data write step of writing a plurality of kinds of data in a matrix-shaped data write block with a plurality of rows and a plurality of columns;
a data read step of reading out the data in two directions that are different from a direction in which the data is written and are parallel to each other;
a disposing step of disposing the data read out in the order in which the data is read out; and
a transmitting step of transmitting the data disposed in the disposing section.
